(19) United States
(12) Patent Application Publication
(10) Pub. No.: US 2005/0184288 A1
(43) Pub. Date: Aug. 25, 2005

(54) Semiconductor device having a second level of metallization formed over a first level with minimal damage to the first level and method

(76) Inventors: Tien-I Bao, Hsin-Chu (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/800,510

(22) Filed: Mar. 15, 2004

Related U.S. Application Data
(60) Provisional application No. 60/547,697, filed on Feb. 25, 2004.

(51) Int. Cl. H01L 51/00

(52) U.S. Cl. 257/40

(57) ABSTRACT

A semiconductor device having an upper level of metallization interconnected with a lower level of metallization and a method of forming the device is provided. Accordingly, the process of the invention includes capping the lower level of metallization with an thin stop layer having a thickness of less than 300 Å and preferably about 100 Å such that the etching and ashing processes of removing photoresist and intermediate portions of etch stop layer is accomplished without damage to the lower level metallization.

This application claims the benefit of U.S. Provisional Application No. 60/547,697, filed on Feb. 25, 2004, entitled A Semiconductor Device Having a Second Level of Metallization Formed Over a First Level With Minimal Damage to the First Level and Method, which application is hereby incorporated herein by reference.

### TECHNICAL FIELD

This invention relates generally to semiconductor processing, and more particularly to a method of forming a second level of metallization that contacts a first level of metallization with minimal damage to the first level resulting from opening a dielectric used to pattern the second level.

### BACKGROUND

As is well known by those skilled in the art, a continuing goal in manufacturing and production of semiconductors is a reduction in size of components and circuits with the concurrent result of an increase in the number of circuits and/or circuit elements such as transistors, capacitors, etc., on a single semiconductor device. This relentless and successful reduction in size of the circuit elements has also required reduction in the size of the conductive lines connecting devices and circuits.

In the past, aluminum was used as the metal interconnect lines and silicon oxide as the dielectric. However, newer manufacturing techniques now favor copper as the metal for interconnect lines and various low K materials (organic and inorganic) are favored as the dielectric material. Not surprisingly, these material changes have required changes in the processing methods. In particular, because of the difficulty of etching copper without also causing unacceptable damage to the copper and/or dielectric material, the technique of forming the metal interconnect lines has experienced significant changes. Namely, whereas aluminum interconnects could be formed by depositing a layer of aluminum and then using photoresist, lithography, and etching to leave a desired pattern of aluminum lines, the formation of copper interconnect lines are typically formed by a process now commonly referred to as a Damascene process. The Damascene process is almost the reverse of etching, and simply stated a trench, canal or via is cut, etched or otherwise formed in the underlying dielectric and is then filled with metal (i.e., copper).

The Damascene process has allowed even further reduction in the size of interconnect lines and the space between interconnect lines. Unfortunately, as the space between interconnecting lines has decreased, the line-to-line capacitance has increased.

As stated above, the change in materials and processing steps has resulted in a new set of manufacturing challenges. For example, patterning and etching the dielectric layer that supports and surrounds a via interconnecting an upper or second metallization layer to a lower metallization level, and then removing the resist or hard mask by the typical “ashing” process often results in considerable damage to the top surface of the copper of the lower metallization at the point of the interconnection. This damage may result in decreased yields, and therefore, etching techniques and the method of removal of resist needs some adjustments.

### SUMMARY OF THE INVENTION

These and other problems are generally solved or circumvented, and technical advantages are generally achieved by embodiments of the present invention, which provide semiconductor devices and methods of manufacturing the semiconductor devices having an upper level of metallization interconnected to a lower level of metallization. Unlike the prior art processes, the processes of the present invention provide for the interconnection between the two levels of metallization with minimal damage to the lower metallization level.

In accordance with an embodiment of the present invention, the method provides a substrate having a top surface that defines and surrounds the lower level of metallization, which is typically made of copper. A thin layer of stop material is then deposited by any suitable method such as CVD (Chemical Vapor Deposition), PVD (Plasma Vapor Deposition), ALD (Atomic Layer Deposition) and Ion Beam Deposition. As used herein, the term “thin” is defined to include layers of about 300 Å and less. A 100 Å thickness of SiC (Silicon Carbide) has been found to be particularly effective. Other suitable materials include SiCN, SiCO, SiN, SiO, and SiOCH. Further, the layer of stop material may comprise two or more layers of different ones of the suitable materials. A layer of IMD (inter-metal dielectric) is then deposited over the thin stop layer and a layer of resist is then deposited and patterned over the layer of IMD to define a mask. The layer of IMD is etched using the patterned resist as a mask such that apertures such as trenches and vias are etched into the IMD. The etched apertures will include at least one via that is etched completely through the IMD layer and exposes the thin stop layer. The patterned resist is then removed by an “ashing” process. However, unlike prior art methods, removing the thin stop layer capping the lower level of copper can be accomplished without causing excess damage to the copper. A layer of copper or other metal conductor is then deposited in the via and other apertures by the typical Damascene process step.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1A illustrates a prior art method of providing a thick capping layer over a lower level of copper followed by an IMD layer and a patterned resist layer;

FIG. 1B illustrates the damaged lower level copper layer of metallization that results from prior art methods of etching the IMD layer and removing the patterned resist by an “ashing” process;

FIGS. 2A-2F illustrate the formation of a second level of metallization over a first level metallization on a semiconductor device according to the methods that reduce damage to the lower level as taught by the present invention; and

FIGS. 3A-3B show a flow chart illustrating the process steps of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

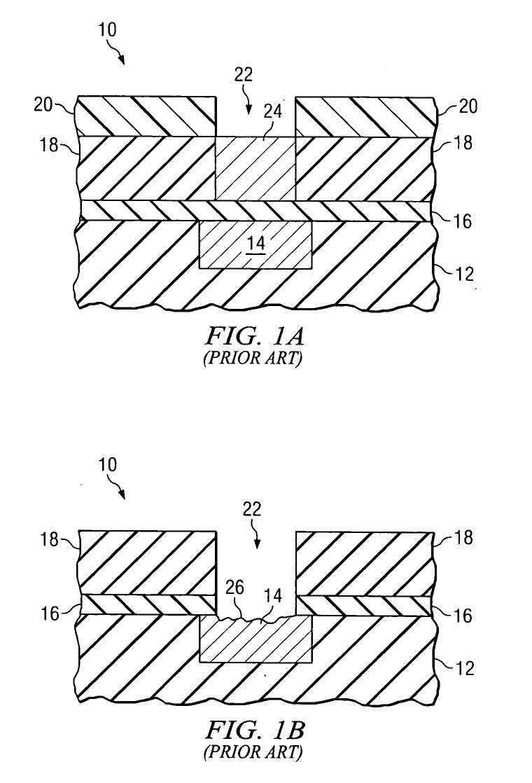

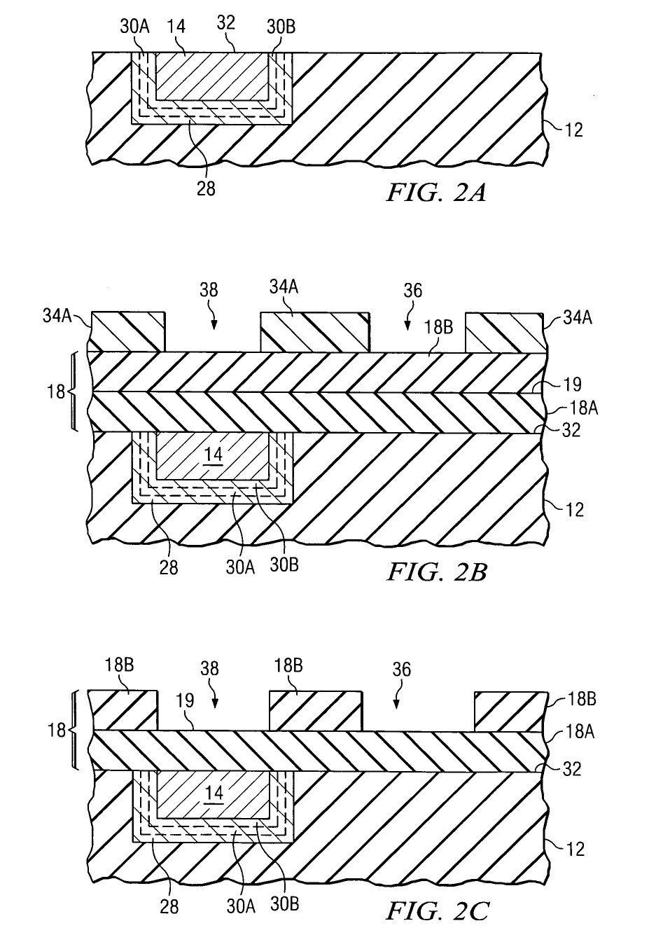

Referring now to FIG. 1A, there is shown a typical prior art semiconductor structure including a substrate 10 having a first layer of non-conductive or dielectric material 12 and at least one conductive or interconnect region 14, such as copper metallization or lines. It should be appreciated that the term substrate 10 as used herein may represent one or more layers of various semiconductor devices including interconnecting metallization layers. Thus, the term substrate is intended to be broadly interpreted.

Further, according to the prior art, it is typical to include a thick capping layer 16 used as etch stop or diffusion over the conductive regions 14 of a material such as silicon nitride if still another layer of metallization is to be formed over the first layer of dielectric material 12 and first metallization 14. Capping layer 16 is typically deposited to a thickness substantially greater than 300 Å. A second layer of dielectric 18, commonly referred to as an ILD (InterLayer Dielectric), or IMD (InterMetal Dielectric) is then deposited over the thick capping layer 16. A layer of resist 20, such as a photoresist, is then deposited over the IMD layer 18 and patterned to define apertures such as trenches for interconnect lines and at least one via in the second layer or IMD layer 18 that will comprise the second or upper level of metallization. The patterned resist 20 is then used as a hard mask to etch the pattern or layout of the second level of metallization in the IMD layer 18, including for example, via 22 that is etched completely through the dielectric layer 18, and as indicated by the shaded cross-hatch portion 24 of the IMD layer 18. The patterned resist layer 20 and the thick capping layer 16 at the bottom of via 22 is then typically removed by an oxidation process at a high temperature commonly referred to as an “ashing” process as is well known by those skilled in the art. The apertures, including via 22 defined in the IMD layer 18, are then filled with a conductive metal such as copper. However, referring now to FIG. 1B, and as will also be appreciated by those skilled in the art, opening or etching the dielectric layer 18 and the ashing process steps discussed above often result in substantial damage to the top surface 26 of the copper first level of metallization 14 as shown. This damage to top surface 26 may result in an unsatisfactory contact to a copper interconnect formed by via 22 filling between the first or lower level of metallization 14 and a second or upper level of metallization.

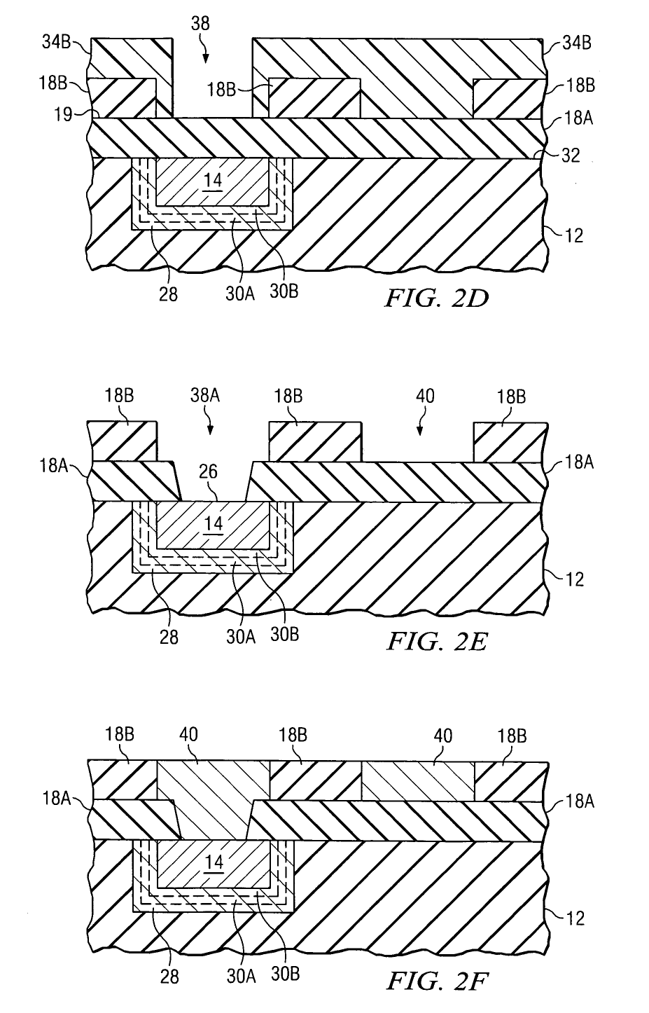

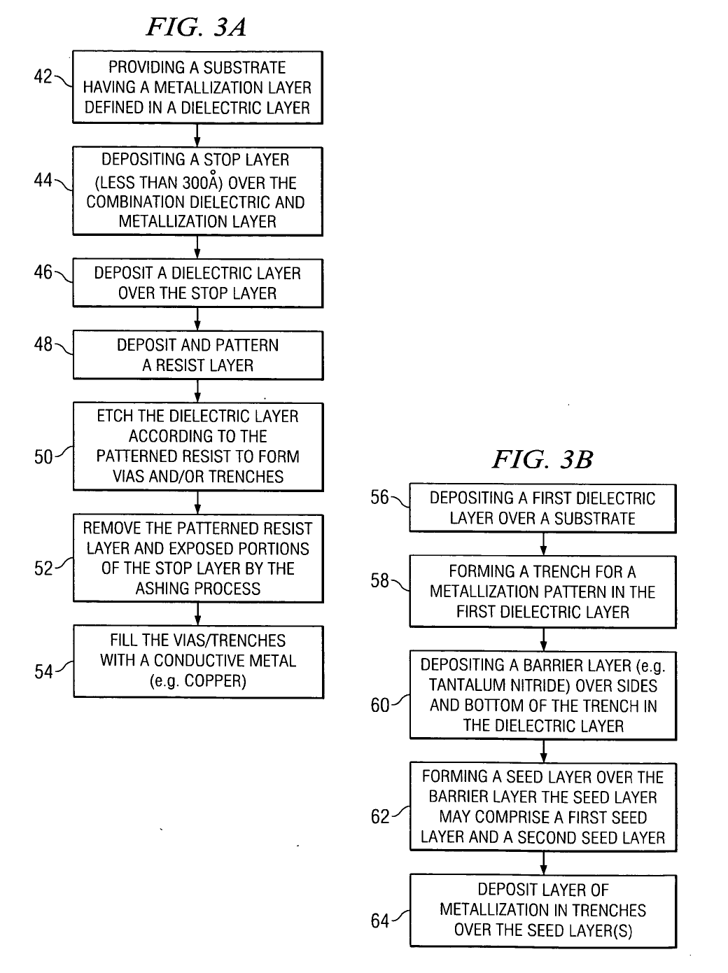

Referring now to FIGS. 2A-2F and FIGS. 3A and 3B, there is illustrated a process for eliminating or substantially reducing such damage to the interconnect between an upper and a lower level of metallization. Elements of FIGS. 2A-2F that are the same as elements in FIGS. 1A and 1B carry the same reference numbers. As is well known by those skilled in the art, and as was discussed above, the use of the Damascene process and the use of metals such as copper as the interconnecting layers has created various new problems not experienced with the older etched aluminum process for forming a metallization layer. For example, still another problem experienced when the conducting or interconnecting lines 14 are made of copper or copper containing materials, is that the copper may diffuse into the surrounding non-conductive dielectric or substrate areas 12 if steps are not taken to prevent such diffusion. Thus, as shown in FIG. 2A, there may also be included a barrier layer 28, which stops or hinders the diffusion of the copper ions from the copper interconnecting strip 14 into the surrounding non-conductive dielectric portions or regions 12 of the substrate 10. Suitable barrier layers are well known in the art and include, for example only, Ta (tantalum), TaN (tantalum nitride), Ti (titanium) and TiN (titanium nitride) and various combinations of these and other materials. Thus, when this barrier layer 28 is provided, diffusion of the copper 14 into the surrounding materials is slowed if not substantially eliminated.

Further, it is often advantageous to include at least one metal seed layer 30. Although a single seed layer maybe sufficient, a preferable technique is to deposit a first metal seed layer 30a, which may be substantially non-conformal to the trenches supporting metal 14. Metal seed layer 30a is then followed by a second seed layer 30b that provides substantially smooth surfaces. It is not even necessary, however, that both of the seed layers be made of the same material. As an example, either one or both of the seed layers may be selected from such materials as Cu (Copper), Al (Aluminum), Ag (Silver), Au (Gold), W (Tungsten) and TaN (Tantalum Nitride). Likewise, both the first and second seed layers may be deposited by the same deposition method or a different method, as appropriate. Suitable methods include PVD (Plasma Vapor Deposition), CVD (Chemical Vapor Deposition) ALD (Atomic Layer Deposition) and/or ECP (Electro Chemical Process). The apertures, trenches and vias are then filled with the metallization (such as copper for example).

Then according to the present invention, instead of a thick capping layer (greater than 300 Å) as was used in the prior art, a thin (less than 300 Å) stop layer 32 is deposited as an etch stop or diffusion stop. Preferably, stop layer 32 is deposited to a thickness of about 100 Å. The stop layers may be organic or inorganic and suitable materials for use as stop layer 32 may be metal or non-metal and include silicon, nitrogen, carbon, oxygen and/or hydrogen containing materials such as SiC, SiCN, SiCO, SiN, SiO, SiOCH and other carbon-like materials. Further, as will be appreciated by those skilled in the art, the thin stop layer 32 may be multilayered and deposited in more than one step, and the various multilayers may be of different suitable materials. Suitable methods for depositing a single or multi thin layer of selected suitable materials include a PVD (Plasma Vapor Deposition) process, a CVD (Chemical Vapor Deposition) process, and ALD (Atomic Layer Deposition) process and an Ion Beam Deposition process. Further, the thin layer is preferably deposited at a temperature of between about 200° C. and 500° C.

Referring now to FIG. 2B, the thin stop layer 32 is followed by the deposition of a dielectric layer 18 after which the dielectric layer 18 is covered by a resist, which is patterned to define apertures such as trenches and vias in the IMD layer 18. Depending on the selected Damascene process, dielectric layer 18 may be comprised of a first layer, such as IMD (inter-metal dielectric) layer 18a, an etch stop layer 19 and a second dielectric layer 18b.

For example only, referring again to FIG. 2B, a first layer of resist 34a is patterned to define apertures or trenches 36 and 38 on the top of IMD layer 18b. It should be noted that trench 38 is located directly above copper line 14. The trenches 36 and 38 are then etched through dielectric layer 18b down to etch stop layer 19 and the first layer of resist 34a is stripped as shown in FIG. 2C. Then, according to one embodiment of the invention, a second layer of resist 34b is deposited over the IMD layer 18b, which fills the etched trenches 36 and 38. The second layer of resist 34b is then patterned to define the location of at least one interconnect via as shown in FIG. 2D. Layer 18a is then further etched such that via 38a extends completely through the IMD layer 18b and dielectric layer 18a. After the etching is complete, the resist layer 34b and the exposed portion 40 of the thin stop layer or capping layer 32 is stripped and/or removed. Removal of the resist and exposed stop layer is typically by the ashing process to produce the structure shown in FIG. 2E. It is important to note at this point that the top surface 26 of copper layer 14 is not damaged as occurred in the prior art processes. The trenches 36 and 38 and the via 38a are then filled with a metal such as copper 40 according to the dual Damascene process to produce the structure of FIG. 2F.

Referring to FIG. 3A, there is illustrated a flow diagram of the process of the present invention as discussed above. As shown, substrate 10 having a dielectric layer 12 defining the copper or metallization layer 14 is provided as shown by process step 42. Then, according to the present invention, a stop layer 32 having a thickness of less than 300 Å is deposited over the combination dielectric 12 and metallization layer 14 as shown by process step 44 and will serve as a stop layer. The IMD or ILD layer 18 is then deposited according to process step 46, followed by the deposition and patterning of a resist layer 20, as shown at step 48. The IMD layer 18 is then etched (step 50) and the resist and exposed portions of the thin stop layer 32 are removed by the ashing process indicated at step 52. Finally, the trenches and vias are filled with a metal, such as copper, as shown at step 54.

FIG. 3B illustrates details comprising the steps for providing the substrate 10 shown at step 42 of FIG. 3A. As shown, a first dielectric layer is deposited over the substrate as shown at step 56. Then, in a manner well know by those skilled in the art, a trench for the metallization layer is formed as indicated at step 58. A barrier layer 28, such as tantalum nitride, is then deposited over the sides and bottom of the trench as indicated at step 60. The barrier layer 28 is then followed by a seed layer 30, which may be comprised of a first seed layer and a second seed layer as indicated by step 62. Finally, a suitable metal, such as copper, aluminum, gold, silver, tungsten or tantalum nitride, is deposited in the trenches to form the first level of metallization.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a first dielectric layer defining a copper containing feature; and
a thin stop layer formed on said first dielectric layer, said copper containing feature substantially free of damage resulting from forming an opening through said thin stop layer and a dielectric layer covering said thin stop layer.

2. The semiconductor device of claim 1 wherein said thin stop layer has a thickness less than 300 Å.

3. The semiconductor device of claim 1, wherein said thin stop layer has a thickness of about 100 Å.

4. The semiconductor device of claim 1 wherein damage to said copper containing feature is limited to a recess of less than about 150 Å in the copper at the at via bottom.

5. The semiconductor device of claim 1 wherein said thin stop layer is multilayered.

6. The semiconductor device of claim 1 wherein said thin stop layer comprises an organic material.

7. The semiconductor device of claim 1 wherein said thin stop layer contains a metal.

8. The semiconductor device of claim 1 wherein said thin stop layer includes at least one of the materials selected from the group consisting of SiC, SiCN, SiCO, SiN, SiO, SiOCH, and combinations thereof.

9. A semiconductor device comprising an upper level of metallization covering a lower level of metallization which is substantially free of damage, said device comprising:
a substrate having a top surface, said top surface defining said lower level of metallization;
an etch stop layer having a thickness of less than 300 Å deposited on top of said lower level of metallization;
a patterned layer of IMD (inter-metal dielectric) covering and in contact with said etch stop layer, said patterned layer of IMD defining a layout for said upper layer of metallization, said layout further including at least one area, where said layer of IMD and said etch stop layer are completely etched through said lower level of metallization substantially damage free; and
a metal layer filling said layout etched in said IMD layer forming said upper layer of metallization and in contact with said lower level of metallization.

10. The semiconductor device of claim 9 wherein said etch stop layer has a thickness of less than about 300 Å.

11. The semiconductor device of claim 9 wherein said etch stop layer has thickness of about 100 Å.

12. The semiconductor device of claim 9 wherein said etch stop layer is multilayered.

13. The semiconductor device of claim 9 wherein said etch stop layer includes an organic material.

14. The semiconductor device of claim 9 wherein said etch stop layer contains a metal.

15. The semiconductor device of claim 9 wherein said layer of etch stop layer comprises at least one of the materials selected from the group consisting of SiC, SiCN, SiCO, SiN, SiO and SiOCH.

16. The semiconductor device of claim 9 wherein said lower level of metallization comprises copper.

17. The semiconductor device of claim 9 wherein said metal layer filling said layout etched in said IMD layer comprises copper.

18. The semiconductor device of claim 9 wherein said substrate includes a dielectric layer and wherein said lower level of metallization is defined by a trench in said dielectric layer and further comprising a first metal seed layer on the bottom and side walls of said trench and a metal filling said trench.

19. The semiconductor device of claim 18 comprising a second metal seed layer between said first metal seed layer and said metal filling said trench.

20. The semiconductor device of claim 18 wherein said first metal seed layer is selected from the group consisting of copper, aluminum, gold, silver, tungsten and tantalum nitride.

21. The semiconductor device of claim 18 wherein at least one of said first and second metal seed layers are selected from the group consisting of copper, aluminum, gold, silver, tungsten and tantalum nitride.

22. The semiconductor device of claim 18 wherein said first and second metal seed layers are made from the same metal.

23. The semiconductor device of claim 17 wherein said metal filling said trench comprises copper.

24. A method for processing a semiconductor structure defining a metallization layer which results in said metallization layer being substantially free of damage comprising the steps of:
capping a top surface of said semiconductor structure that defines said metallization layer with a thin stop layer;
forming a layer of dielectric over said layer of thin stop, said layer of dielectric defining at least one area where said thin stop layer is exposed; and
removing said exposed thin stop layer to expose a top surface of said metallization layer which is substantially free of damage.

25. The method of claim 24 wherein said step of forming a layer of dielectric comprises forming a patterned layer of dielectric according to a patterned layer of resist, said patterned layer of dielectric defining a layout for an upper layer of metallization, and said step of removing further comprises removing said patterned layer of resist.

26. The method of claim 24 wherein said thin stop layer is deposited to a thickness of less than about 300 Å.

27. The method of claim 24 wherein said thin stop layer is deposited to a thickness of about 100 Å.

28. The method of claim 25 further comprising the step of filling said layout etched in said dielectric layer with a conductive metal, such as copper.

29. The method of claim 24 wherein said thin stop layer is an organic material.

30. The method of claim 24 wherein said thin stop layer contains a metal.

31. The method of claim 24 wherein said thin stop layer comprises at least one of the materials selected from the group consisting of SiC, SiCN, SiCO, SiN, SiO, SiOCH, and combinations thereof.

32. The method of claim 24 wherein said thin stop layer is multilayered.

33. The method of claim 24 wherein said thin stop layer is deposited by at least one of the processes selected from the group consisting of PVD (Plasma Vapor Deposition), CVD (Chemical Vapor Deposition), ALD (Atomic Layer Deposition), and Ion Beam Deposition.

34. The method of claim 24 wherein said thin stop layer is deposited at a temperature of between about 200° C. and about 500° C.

35. The method of claim 24 further comprising the following steps for forming said semiconductor substrate:
depositing a dielectric layer;
forming a trench in said dielectric layer;
forming a metal seed layer over the dielectric layer with said trenches; and
depositing a metal in said trench.

36. The method of claim 35 further comprising forming a barrier layer over the surface of said trench prior to forming said seed layer.

37. The method of claim 36 wherein said barrier layer includes at least one of the materials selected from the group consisting of Ta, TaN, Ti, TiN, and combinations thereof.

38. The method of claim 37 wherein said step of forming a metal seed layer comprises the step of forming a first metal seed layer and then forming a second metal seed layer over said first seed layer.

39. The method of claim 38 wherein the surface of said second metal seed layer has a smooth surface.

40. The method of claim 37 wherein at least one of said first and second metal seed layers are selected from the group consisting of copper, aluminum, gold, silver, tungsten and tantalum nitride.

41. The method of claim 40 wherein said metal seed layers are deposited by a process selected from the group consisting of PVD (Plasma Vapor Deposition), CVD (Chemical Vapor Deposition), ALD (Atomic Layer Deposition), and ECP (Electro Chemical Process).

42. A method of forming the layout for an upper level of metallization in a semiconductor with reduced damage to a lower level of metallization comprising the steps of:
providing a substrate having a surface, said surface including a top surface of said lower level of metallization;
capping said lower level of metallization with a stop layer deposited to a thickness of less than 300 Å over said surface;
forming a patterned layer of dielectric over said etch stop layer according to a patterned layer of resist on said dielectric layer, said patterned dielectric layer defining said layout for an upper level of metallization, and said layout including at least one area where said etch stop layer is exposed; and
removing said patterned resist and said exposed etch stop layer to expose, substantially damage free, a portion of said top surface of said lower level of metallization.

43. A method of forming an upper level of metallization in a semiconductor device with reduced damage to a lower level of metallization comprising the steps of:
providing a substrate having a top surface, said top surface defining said lower level of metallization;
capping said lower level of metallization with a stop layer deposited to a thickness of less than 300 Å over said top surface;
depositing a layer of inter-metal dielectric (IMD) over said stop layer; depositing and patterning a layer of resist to define a patterned mask over said layer of IMD;
etching said layer of IMD to remove material according to said mask, said removed material defining the layout for an upper level of metallization, and said layout including at least one area where said layer of IMD is completely etched through to expose said stop layer;
removing said patterned resist and said exposed stop layer; and
filling said layout etched in said IMD layer with metal to form said upper layer of metallization.
